(19) United States
(12) Patent Application Publication
(10) Pub. No.: US 2022/0181846 A1
(43) Pub. Date: Jun. 9, 2022

(54) OPTICAL MODULATOR AND METHOD FOR MANUFACTURING THE SAME

(71) Applicant: Xiamen San'An Integrated Circuit Co., Ltd., Xiamen (CN)

(72) Inventors: Weizhong SUN, Xiamen (CN); Wenbi CAI, Xiamen, (CN)

(21) Appl. No.: 17/652,657

(22) Filed: Feb. 25, 2022

Related U.S. Application Data
(63) Continuation-in-part of application No. PCT/CN2020/103337, filed on Jul. 21, 2020.

(30) Foreign Application Priority Data
Aug. 29, 2019 (CN) 201910806579.3

(51) Int. Cl. H01S 5/06; H01S 5/042; H01S 5/22; H01S 5/12

(52) U.S. Cl. CPC H01S 5/0614; H01S 5/1237; H01S 5/22; H01S 5/04256

(57) ABSTRACT

An optical modulator includes a light-emitting device and an upper electrode disposed on the light-emitting device. The upper electrode includes at least one first electrode portion for injecting a direct current to form a direct-current modulated segment, and a second electrode portion for injecting an alternating current to form an alternating-current modulated segment. The at least one first electrode portion and the second electrode portion are spaced apart from each other, and have a first length and a second length, respectively. The first length is greater than the second length. A method for manufacturing the optical modulator is also provided herein.

### CROSS-REFERENCE TO RELATED APPLICATION

This application is a bypass continuation-in-part application of PCT International Application No. PCT/CN2020/103337 filed on Jul. 21, 2020, which claims priority of Chinese Invention. Patent Application No. 201910806579.3 filed on Aug. 29, 2019. The entire content of each of the International and Chinese patent application is incorporated herein by reference.

### FIELD

The disclosure relates to a semiconductor device for optical communication, and more particularly to an optical modulator and a method for manufacturing the same.

### BACKGROUND

Conventional directly modulated lasers (DML) have seen wide application in the field of speed communication due to various advantages, such as high photovoltaic conversion efficiency, low power consumption, and cost. However, in high speed communication applications, modulation bandwidth of the DML is limited by the physical structure thereof, and is not suitable for high speed modulation because modulation speeds of greater than 28 Gbps (Giga bit per second) are difficult to acheive. In addition, the DML is difficult to apply in the field of medium and long distance communication (for example, greater than 20 kilometers) because of its large chirping effect. Therefore, an electroabsorption modulated distributed feedback laser (EML) is mainly used for medium and long distance communication. Nevertheless, the manufacturing process of the EML is complicated and difficult, which limits production yield and increases production cost of the EML. Moreover, the power consumption of the EML during operation is much larger than that of the DML. In view of above, the EML is not suitable for 5^{th} generation mobile networks since the EML cannot achieve faster transmission speed or lower cost.

### SUMMARY

An object of the disclosure is to provide an optical oscillator and a method for manufacturing the same, which can alleviate or overcome the aforesaid shortcomings of the prior art. According to a first aspect of the disclosure, an optical modulator includes a light-emitting device and an upper electrode disposed on the light-emitting device.

The upper electrode includes at least one first electrode portion, and a second electrode portion.

The at least one first electrode portion is used for injecting a direct current so as to form a direct-current modulated segment in the light-emitting device in a position beneath the at least one first electrode portion.

The second electrode portion is used for injecting an alternating current so as to form an alternating-current modulated segment in the light-emitting device in a position beneath the second electrode portion.

The at least one first electrode portion and the second electrode portion are spaced apart from each other in an X direction, and have a first length and a second length in the X direction, respectively. The first length is greater than the second length.

According to a second aspect of the disclosure, a method for manufacturing an optical modulator includes the steps of:

a) disposing a first confinement layer, an active layer and a second confinement layer on a substrate in such order, the first and second confinement layers having different conductivity types;

b) forming a waveguide unit on the second confinement layer, the waveguide unit including a ridge waveguide; and

c) forming an upper electrode on the ridge waveguide, the upper electrode including at least one first electrode portion for injecting a direct current and a second electrode segment for injecting an alternating current, the at least one first electrode portion and the second electrode portion being spaced apart from each other in an X direction, and having a first length and a second length in the X direction, respectively, the first length being greater than the second length.

### BRIEF DESCRIPTION OF THE DRAWINGS

Other features and advantages of the disclosure will become apparent in the following detailed description of the embodiment(s) with reference to the accompanying drawings, in which:

FIG. 1 is a schematic view illustrating a first embodiment of an optical modulator according to the disclosure;

FIG. 2 is a schematic view illustrating a first variation of the first embodiment;

FIG. 3 is a schematic view illustrating a second variation of the first embodiment;

FIG. 4 is a schematic view illustrating a second embodiment of the optical modulator according to the disclosure;

FIG. 5 is a flow chart illustrating consecutive steps of a method for manufacturing the second embodiment of the optical modulator;

FIGS. 6 to 14 are schematic views illustrating the consecutive steps of the method for manufacturing the second embodiment of the optical modulator;

FIG. 15 is a schematic view illustrating a third embodiment of the optical modulator according to the disclosure; and

FIG. 16 is a flow chart illustrating consecutive steps of a method for manufacturing the third embodiment of the optical modulator.

### DETAILED DESCRIPTION

Before the disclosure is described in greater detail, it should be noted that where considered appropriate, reference numerals have been repeated among the figures to indicate corresponding or analogous elements, which may optionally have similar characteristics.

It should be noted that, directional terms, such as “upper,” “lower,” “inner,” “outer,” “left,” “right,” “top,” and “bottom” may be used to assist in describing the disclosure based on the orientation of the embodiments shown in the figures. The use of these directional definitions should not be interpreted to limit the disclosure in any way.

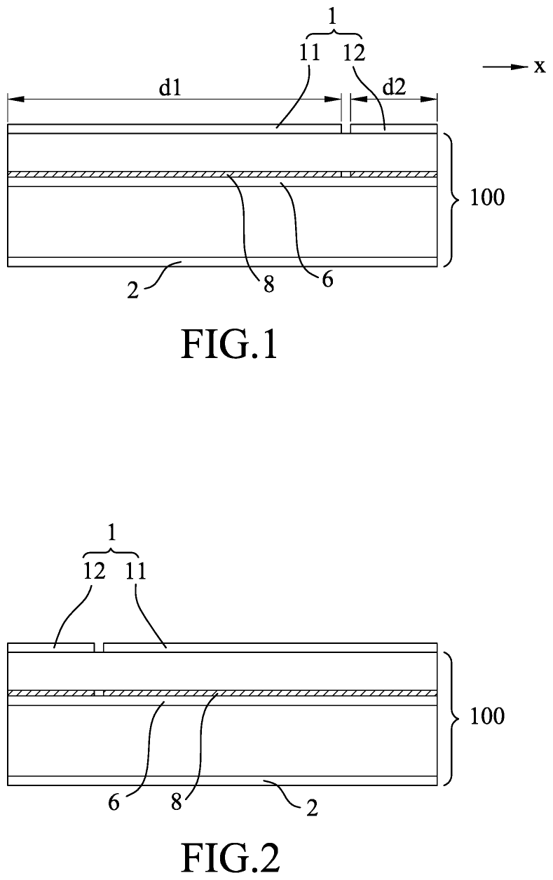

Referring to FIG. 1, a first embodiment of an optical modulator according to the present disclosure includes a light-emitting device 100, an upper electrode 1, and a lower electrode 2.

The light-emitting device 100 includes as active layer 6 and a grating structure 8, which will be described hereinafter. The upper electrode 1 is disposed on the light-emitting device 100, and includes at least one first electrode portion 11 and a second electrode portion 12. The at least one first electrode portion 11 is used for injecting a direct current so as to form a direct-current modulated segment in the light-emitting device 100 in a position beneath the at least one first electrode portion 11. The second electrode portion 12 is used for injecting an alternating current so as to form an alternating-current modulated segment in the light-emitting device 100 in a position beneath the second electrode portion 12.

The at least one first electrode portion 11 is disposed on Lite light-emitting device 100, and proximate to a high reflection (HR) film (not shown) that is disposed on a first side of the light-emitting device 100 (the left side of FIG. 1). The second electrode portion 12 is disposed on the light-emitting device 100, and proximate to an anti-reflection (AR) film (not shown) that is disposed on a second side (the right side of FIG. 1) of the light-emitting device 100 opposite to the first side. In other words, the direct-current modulated segment is located in the first side of the light-emitting device 100 proximate to the high reflection film, and the alternating-current modulated segment is located in the second side of the light-emitting device 100 proximate to the anti-reflection (AR) film.

The at least one first electrode portion 11 and the second electrode portion 12 are both formed on and electrically connected to the active layer 6. The at least one first electrode portion 11 and the second electrode portion. 12 may have charges sharing with the active layer 6. In addition, each of the at least one first electrode portion 11 and the second electrode portion 12 cooperates with a corresponding one of grating strips 82 of the grating structures 8.

In this embodiment, the at least one first electrode portion 11 and the second electrode portion 12 are spaced apart from each other in an X direction, and have first length (d1) and a second length (d2) in the X direction, respectively. The first length (di) is greater than the second length (d2).

In certain embodiments, the first length (d1) may range from 100 μm to 300 μm. The direct-current modulated segment may have a length that is the same as the first length (d1). The light output power and extinction ratio of the optical modulator may be affected by the length of the direct-current modulated segment. The longer the direct-current modulated segment, the larger the light output power of the optical modulator and the smaller the extinction ratio of the optical modulator.

In certain embodiments, the second length (d2) may range from 50 μm to 150 μm. The alternating-current modulated segment may have a length that is the same as the second length (d2). The modulation rate and extinction ratio of the optical modulator may be affected by the length of the alternating-current modulated segment. The shorter the alternating-current modulated segment, the larger the modulation rate of the optical modulator and the smaller the extinction ratio of the optical modulator. The length of the alternating-current modulated segment may vary depending on the desired modulation rate of the optical modulator. It is noted that the length of the direct-current modulated segment should be greater than the length of the alternating-current modulated segment.

In a first variation of the first embodiment, as shown in FIG. 2, the at least one first electrode portion 11 is disposed on the second side (the right side of FIG. 2) of the light-emitting device 100 proximate to the AR film (not shown), and the second electrode portion 12 is disposed on the first side (the left side of FIG. 2) of the light-emitting device 100 proximate to the HR film (not shown). In other words, the direct-current modulated segment and the alternating-current modulated segment are located proximate to the second side and the first side of the light-emitting device 100, respectively.

The optical modulator can be used to increase modulation bandwidth of a semiconductor light source (for example, a semiconductor laser) to attain a high modulation speed, which can be apllicable to high speed transmission. In addition, a difference between a current for digital signal “0” and a current for digital signal “1” becomes smaller in the optical modulator, thereby reducing optical frequency chirping effect, attaining a relatively small dispersion of an optical signal transmitted during optical fiber transmission, and meeting the requirements of long distance communication. The process for manufacturing the optical modulator is relatively simple, which is conducive to obtaining high production yield and low production cost.

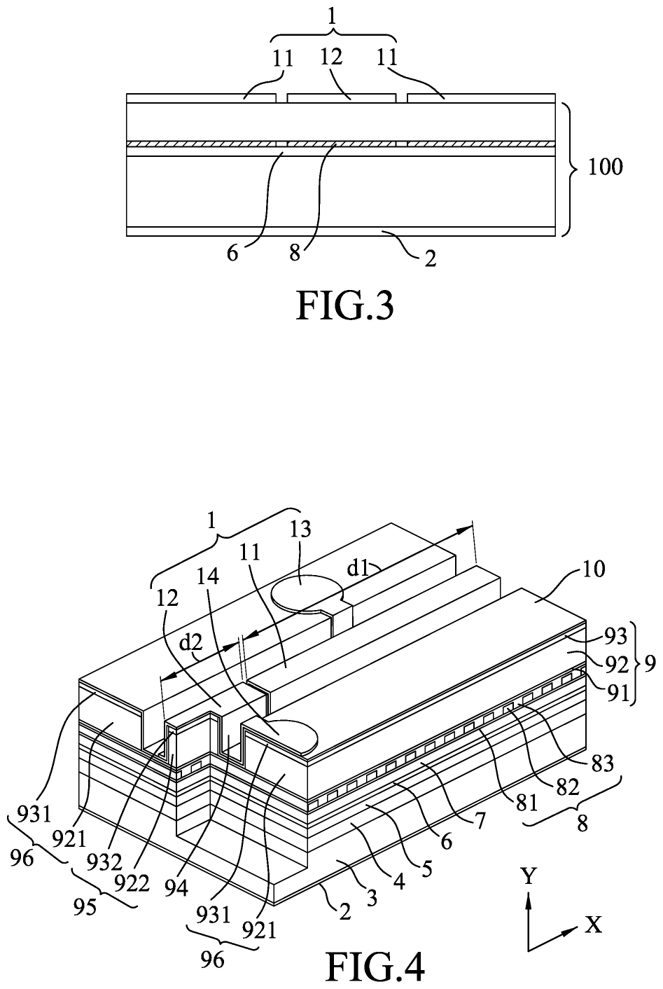

In a second variation of the first embodiment, as shown in FIG. 3, the upper electrode 1 includes two of the first electrode portions 11, and the second electrode portion 12 is located between two of the first electrode portions 11 and is spaced apart from each of the first electrode portions 11. As such, two direct-current modulated segments are respectively formed in a position beneath the two of the first electrode portions 11, and the alternating-current modulated segment is located between the two direct-current modulated segments.

In addition, the two first electrode portions 11 can respectively receive two constant direct currents having the same magnitude it having different magnitudes. The practical method for introducing a current to each of the first electrode portions 11 may vary depending on operation needs. By adjusting position of the first electrode portions 11 and the second electrode portion 12, the optical modulator can have different chirp effects and extinction ratios. The structure of the light-emitting device 100 may vary depending on practical applications. The optical modulator of the first embodiment, which includes the grating structure 8, is adapted for a distributed feedback (DFB) laser. In alternative embodiments, the optical modulator may not include the grating structure, and is adapted for a Fabry-Pérot (FP) laser.

The lower electrode 2 is disposed on the light-emitting device 100 opposite to the upper electrode 1.

Referring to FIG. 4, a second embodiment of the optical modulator according to the disclosure is generally similar to the first embodiment, except for the following differences.

Specifically, the light-emitting device 100 is a semiconductor laser diode (i.e., a DFB laser). In addition to the active layer 6 and the grating structure 8, the light-emitting device 100 further includes a substrate 3, a buffer layer 4, a first confinement layer 5, a second confinement layer 7 a waveguide unit 9, and a passivation layer 10.

The substrate 3 is disposed on the lower electrode 2. The buffer layer 4 is disposed on the substrate 3 opposite to the lower electrode 2. The first confinement layer 5 is disposed on the buffer layer 4 opposite to the substrate 3. The active layer 6 is disposed on the first confinement layer 5 opposite to the buffer layer 4. The second confinement layer 7 is disposed on the active layer 6 opposite to the first confinement layer 5. Each of the first confinement layer 5 and the second confinement layer 7 may be made of a group III to V semiconductor compound (for example, indium aluminum arsenide (TnAlAs) or indium gallium arsenide (InGaAs)). The first and second confinement layers 5, 7 may have different conductivity types (or doping types). In certain embodiments, the doping type of one of the first and second confinement layers 5, 7 is a p-type with a doping concentration ranging from 10¹⁷/cm³ to 10¹⁸/cm³, and the doping type of the other one of the first and second confinement layers 5, 7 is an n-type with a doping concentration ranging from 10¹⁷/cm³ to 10¹³ m³.

The The grating structure 8 is disposed on the second confinement layer 7 opposite to the active layer 6. The grating structure 8 includes a first cladding layer 81, a plurality of grating strips 82, and a second cladding layer 83. The first cladding layer 81 and the second cladding layer 83 are configured to permit the grating strips 82 to be disposed therebetween. The first cladding layer 81 is epitaxially grown on the second confinement layer 7 opposite to the active layer 6. The first cladding layer 81 can be used to provide a flat surface for the grating strips 82 formed thereon, and protect the grating strips 82. The grating strips 82, which are formed on the first cladding layer 81, extend in a Y direction transverse to the X direction, and are displaced from each other in the X direction. The grating strips 82 can be used to diverge light based on the principle of multiple diffraction. The second cladding layer 83 are disposed on the first cladding layer 81 and the grating strips 82. In addition, the second cladding layer 83 not only covers the grating strips 82, but fills a gap among the grating strips 82 to thereby stabilize and protect the grating strips 82.

The waveguide unit 9 is disposed on the grating structure 8 opposite to the second confinement layer 7. The waveguide unit 9 includes an etch stop layer 91, a capping layer 92, and a contact layer 93. The etch stop layer 91 is disposed on the second cladding layer 83 opposite to the second confinement layer 7. The capping layer 92 is disposed on the etch stop layer 91 opposite to the second cladding layer 83, and has two first lateral portions 921 and a first middle portion 922 which is disposed between the first lateral portions 921 and which is spaced apart from each of the first lateral portions 921. The contact layer 93 has two second lateral portions 931 and a second middle portion 932. The second middle portion 932 is disposed on the first middle portion 922 of the capping layer 92 such that the first and second middle portions 922, 932 together serve as a ridge waveguide 95 extending in the X direction. The two second lateral portions 931 are disposed respectively on the first lateral portions 921 so as to form two lateral waveguides 96 at two opposite sides of the ridge waveguide 95. The ridge waveguide 95 defines two trenches 94 respectively with the lateral waveguides 96 so as to expose two portions of the etch stop layer 91.

The passivation layer 10 includes two layer portions each extending to cover a respective one of the lateral waveguides 96 and an inner surface of a respective one of the trenches 94. A portion of the passivation layer 10 that covers the ridge waveguide 95 may be removed, so as to form a metal contact window 101 (see FIG. 13).

In this embodiment, the etch stop layer 91 is located between the second cladding layer 83 and the capping layer 92. In certain embodiments, the etch stop layer 91 may be located between the first cladding layer 81 and the second confinement layer 7. In other words, the etch stop layer 91 can be located above or below the grating structure 8.

In this embodiment, the upper electrode 1 further includes a first extending portion 13 and a second. extending portion 14. The first extending portion 13 extends from the first electrode portion 11 to cover the passivation layer 10. The second extending portion extends from the second electrode portion 12 to cover the passivation layer 10. The first extending Portion 13 and the second extending portion 14 are located at two opposite sides of the metal contact window 101 (or the upper electrode 1). In alternative embodiments, the first extending portion 13 and the second extending portion 14 may be located at a same tide of the metal contact window 101. The first extending portion 1.3 and the second extending portion 14 respectively extend from the first electrode portion. 11 and the second electrode portion 12 in a direction perpendicular to a length direction of the grating strips 82.

The direct-current modulated segment is formed between the first electrode portion 11 and the substrate 3. The first electrode portion 11 can receive a constant direct current through the first extending portion 13. The alternating-current modulated segment is formed between the second electrode portion 12 and the substrate 3. The second electrode portion. 12 can receive an alternating modulation current through the second extending portion 14.

In certain embodiments, the direct-current modulated segment of the optical modulator may receive a constant current ranging from 20 mA to 50 mA, and the alternating-current modulated segment of the optical modulator may receive a bias current ranging from 5 mA to 10 mA. In addition, the alternating-current modulated segment or the optical modulator may be supplied with an alternating modulation current to thereby modulate the light output power of the optical modulator.

The optical modulator of this disclosure can function as a DFB laser with a continuous power and a high direct modulation rate. By reducing the length of the alternating-current modulated segment of the optical modulator, the optical modulator might attain high speed modulation. In addition, because a current flowing in the alternating-current modulated segment is variable and a current flowing in the direct-current modulated segment is constant, the optical modulator might have different chirp and extinction ratios by having multiple current modulated segments and by adjusting the location of the direct-current modulated segment. In this embodiment, the length of the direct-current modulated segment may be 200 μm, and the length of the alternating-current modulated segment may be 50 μm.

In addition, an emission wavelength of the optical modulator may be determined by a grating pitch of the direct-current modulated segment. In certain embodiments, the grating strips 82 in the direct-current modulated segment may have a grating pitch ranging from 160 nm to 270 nm. For example, the grating pitch of the grating strips 82 in the direct-current modulated segment may be 202 cm, and the grating pitch of the grating strips 82 in the alternating-current modulated segment may be 201.7 nm.

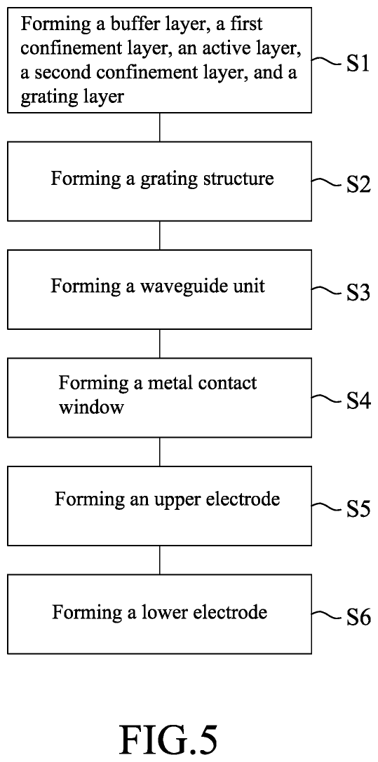

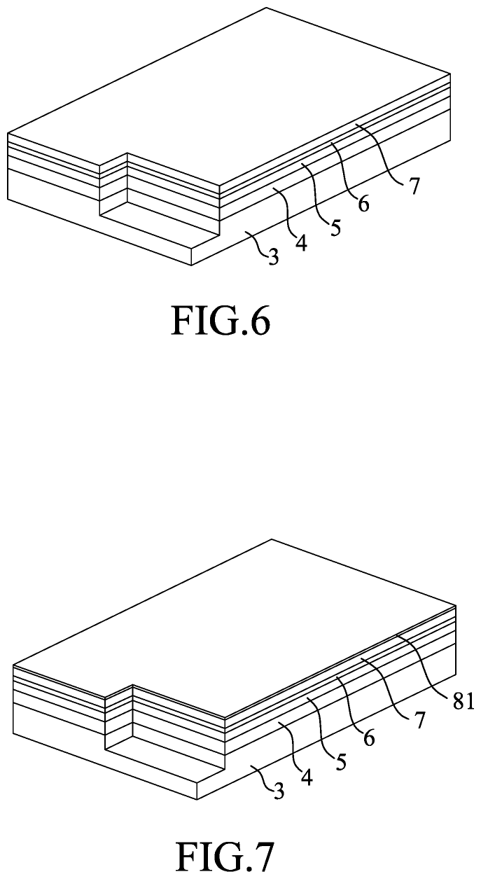

Referring to FIG. 5, this disclosure also provides a method for manufacturing the second embodiment of the optical modulator, which includes the following consecutive steps S1 to S6. FIGS. 6 to 14 illustrate schematic views of the intermediate stages of the method for making the second embodiment of the optical modulator.

In step S1, the buffer layer 4, the first confinement layer 5, the active layer 6, the second confinement layer and a grating layer are epitaxially formed on the substrate 3 in such order, as shown in FIGS. 6 and 7.

The substrate 3 may be made of indium phosphide (InP), and may be subjected to an annealing treatment and a surface cleaning treatment.

The buffer layer 4 is epitaxially grown on the substrate 3. The buffer layer 4 may be made of indium phosphide (InP).

After formation of the buffer layer 4, the first confinement layer 5 is epitaxially grown on the buffer layer 4 opposite to the substrate 3.

After formation of the first confinement layer 5 the active layer 6 is epitaxially grown on the first confinement layer 5 opposite to the buffer layer 4. The active layer 6 may be formed as a quantum well structure, and may be made of indium gallium arsenide phosphate (InGaAsP) or Indium aluminum germanium arsenide (InAlGaAs). The active layer 6 may be grown using a carrier gas (for example, nitrogen) at a constant temperature or a dual temperature.

After formation of the active layer 6, the second confinement layer 7 and the grating layer are sequentially and epitaxially grown on the active layer 6 opposite to the first confinement layer 5.

The grating layer includes the first cladding layer 81 and a grating material layer (now shown) disposed on the first cladding layer 81 opposite to the second confinement layer 7.

The first cladding layer 81 is grown on the second confinement layer 7 opposite to the active layer 6. The first cladding layer 81 may be made of InP.

After formation of the first cladding layer 81, the grating material layer is grown on the first cladding layer 81 opposite to the second confinement layer 7. The grating material layer may be made of indium gallium arsenide phosphide (InGaAsP).

In this step, the buffer layer 4, the first confinement layer 5, the active layer 6, the second confinement layer 7, and the grating layer may be grown using a vapor phase epitaxial growth method, molecular beam epitaxial growth method, or other suitable epitaxial growth methods.

In step S2, the grating material layer is etched to form the grating structure 8.

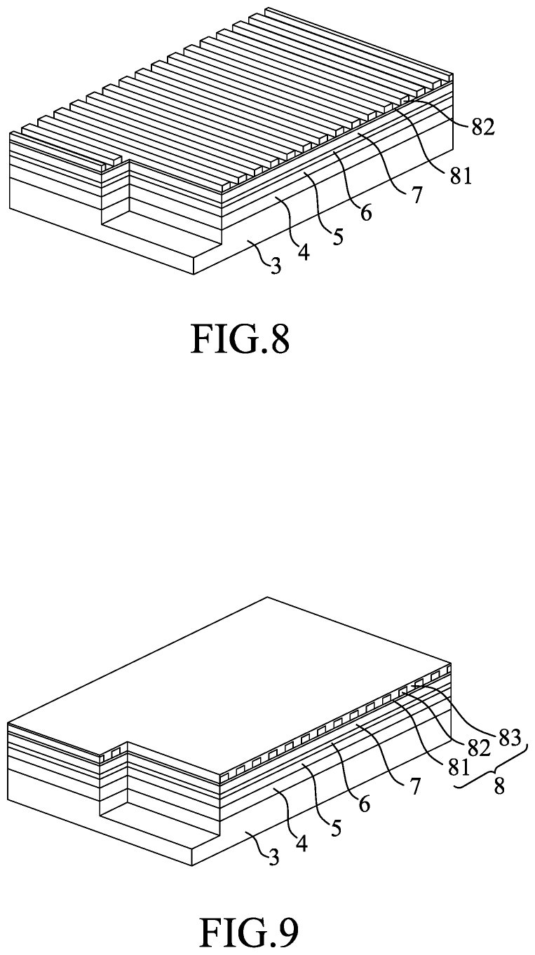

In this step, the grating material layer is first etched to form the grating strips 82 that are disposed in parallel and that are spaced apart from each other, as shown in FIG. 8.

After formation of the grating strips 82, the second cladding layer 83 is grown on the grating strips 82 opposite to the first cladding layer 81, as shown in FIG. 9. The second cladding layer 83 may be made of InP. The first cladding layer 81, the grating strips 82, and the second cladding layer 83 constitute the grating structure 8.

In step 33, the waveguide unit 9 is formed on the grating structure 8 opposite to the second confinement layer 7.

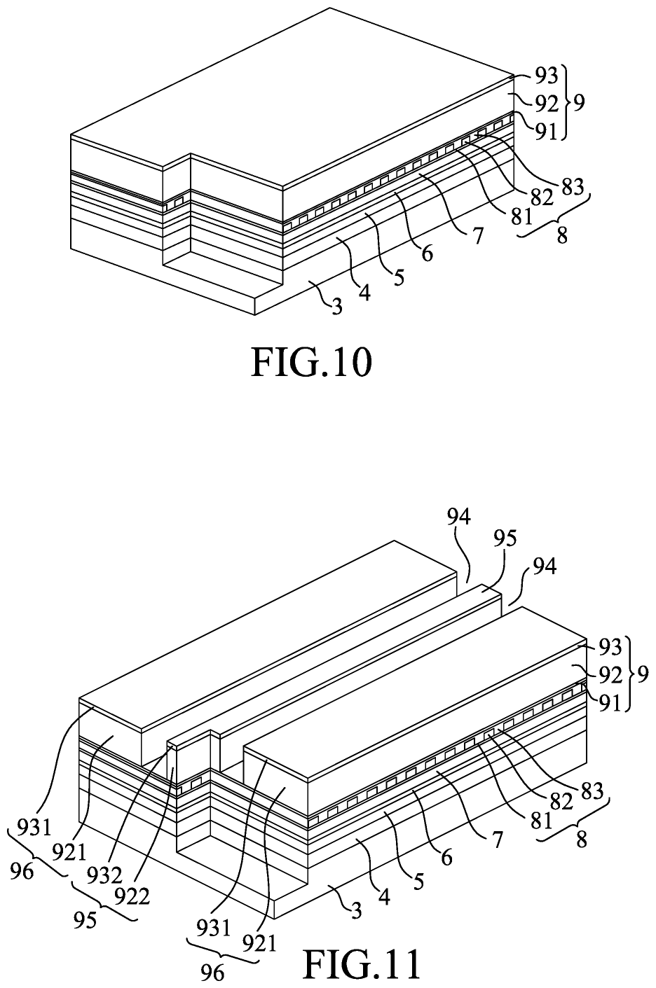

In this step, as shown in FIG. 10, the etch stop layer 91, the capping layer 92, and the contact layer are sequentially and epitaxially grown on the grating structure 8. The capping layer 92 may be made of InP or gallium arsenide (GaAs).

After formation of the etch stop layer 91, the capping layer 92, and the contact layer 93, the capping layer 92 and the contact layer 93 are patterned to form two trenches 94 which expose two portions of the etch stop layer 91, such that the capping layer 92 is formed into the first middle port on 922 and two first lateral portions 921 at two opposite sides of the first middle portion 922, and such that the contact layer 93 is formed into the second middle portion 932 and two second lateral portions 931, as shown in FIG. 11. The second middle portion 932 is disposed on the first middle portion 922 to together serve as the ridge waveguide 95. The second lateral portions 931 are disposed respectively on the first lateral portions 921, so as to form two lateral waveguides 96 at two opposite sides of the ridge waveguide 95.

In step S4, the metal contact window 101 is formed on the waveguide unit 9.

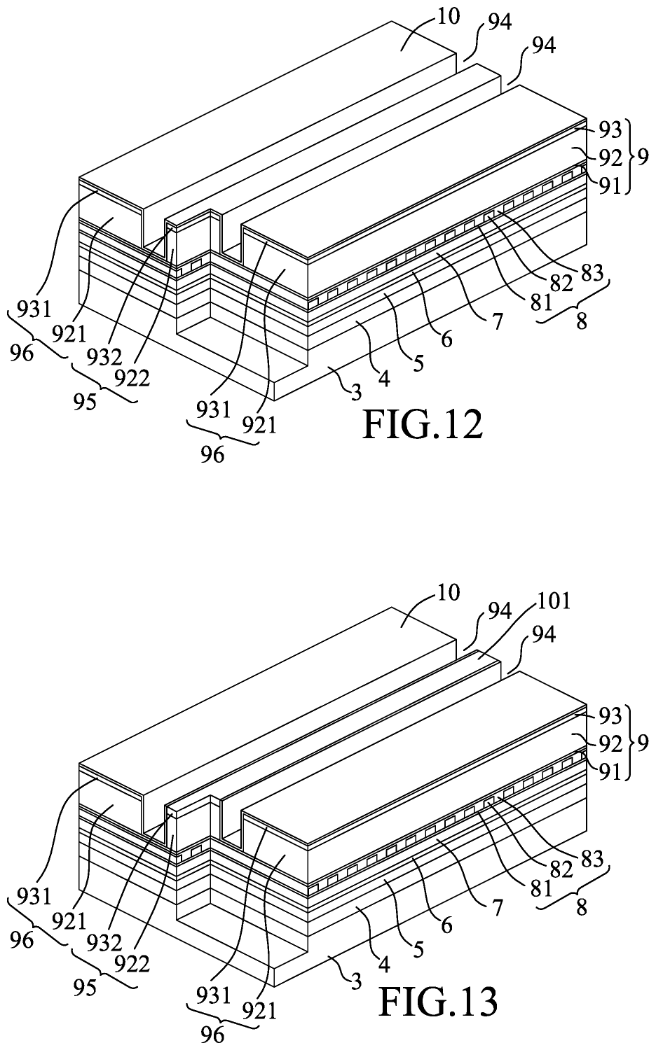

In this step, each of the two layer portions of the passivation layer 10 is deposited and extends to cover the respective one of the lateral waveguides 96, the inner surface of the respective one of the trenches 94 and the ridge waveguide 95, as shown in FIG. 12.

As shown in FIG. 13, after formation of the passivation layer 10, the layer portion of the passivation layer 10 that covers the ridge waveguide 95 is removed to expose the second middle portion 932, so as to form, the metal contact window 101.

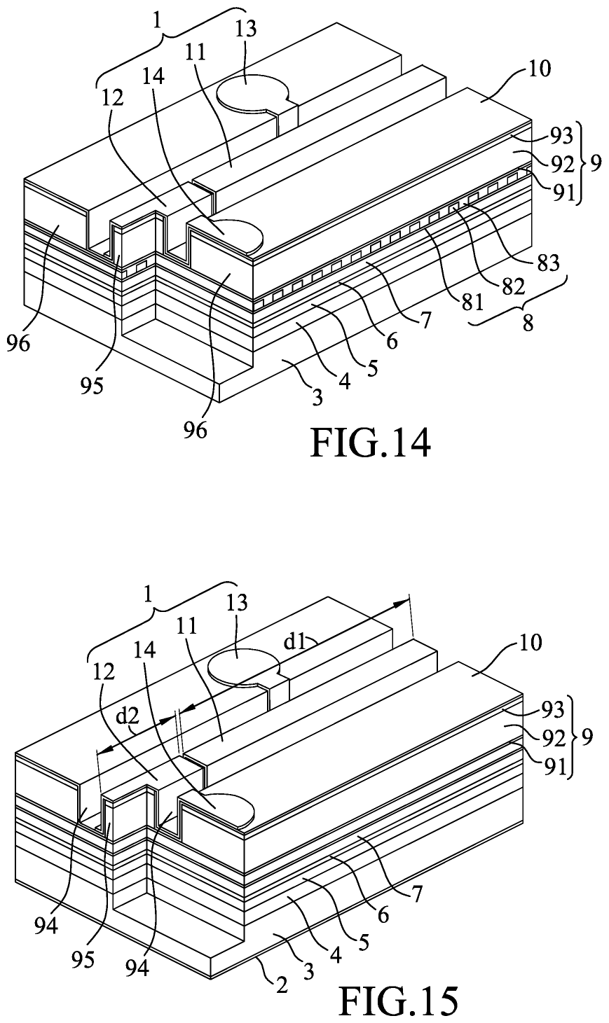

In step S5, as shown in FIG. 14, the upper electrode 1 is formed on the metal contact window 101. The upper electrode 1 may be made of a p-type contact material, such as titanium or gold. The upper electrode 1 may be formed by evaporation or magnetron sputtering. The detailed structure of the upper electrode 1 may be referred back to FIG. 4 and the relevant description thereof.

In step S6, the lower electrode 2 is formed on the substrate 3 opposite to the buffer layer 4. Preferably, in this step, the substrate 3 is thinned from a bottom surface of the substrate 3 that is distal from the buffer layer 4, and the lower electrode J is formed on the bottom surface of the thinned substrate 3.

The lower electrode 2 may be made of an n-type contact material, such as gold, germanium or nickel. The lower electrode may be formed by thermal evaporation or electron beam evaporation. After formation of the electrode 2, the optical modulator as shown in FIG. 4 is obtained.

It is noted that step S6 may be implemented before step S1.

Referring to FIG. 15, a third embodiment of the optical modulator according to the disclosure is generally similar to the second embodiment, except that in the third embodiment, the optical modulator is a FP laser and does not include the grating structure 8.

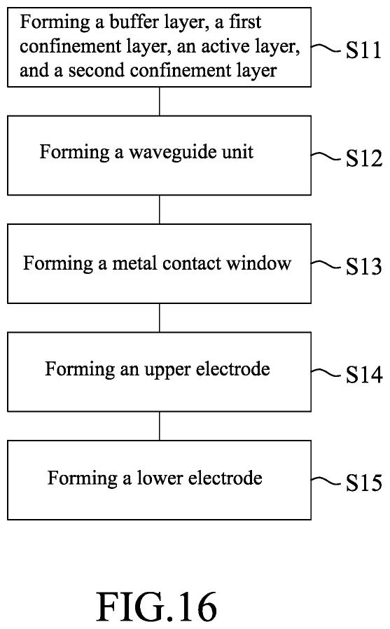

Referring to FIG. 16, this disclosure also provides a method for manufacturing the third embodiment of the optical modulator which includes the consecutive steps S11 to S15. The method for manufacturing the third embodiment of the optical modulator is generally similar to the method for manufacturing the second embodiment, except that the processes for forming the grating layer as mentioned step S1 and the grating structure as mentioned in step S2 are not conducted.

In sum, the optical modulator of this disclosure can have two current modulated segments (i.e., a direct-current modulated segment and an alternating-current modulated segment), or three current modulated segments (i.e., two direct-current modulated segments and an alternating-current modulated segment). Each of the direct-current modulated segment and the alternating-current modulated segment includes the same active layer, and a corresponding portion of the grating structure. In addition, compared with a conventional method for manufacturing the optical modulator, the method of this disclosure only requires adjusting a mask to obtain the required structure of the optical modulator without any additional equipment and process.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. An optical modulator, comprising a light-emitting device and an upper electrode disposed on said light-emitting device, said upper electrode including:
at least one first electrode portion for injecting a direct current so as to form a direct-current modulated segment in said light-emitting device in a position beneath said at least one first electrode portion; and
a second electrode portion for injecting an alternating current so as to form an alternating-current modulated segment in said light-emitting device in a position beneath said second electrode portion,
wherein said at least one first electrode portion and said second electrode portion are spaced apart from each other in an X direction, and have a first length and a second length in the X direction, respectively, the first length being greater than the second length.

2. The optical modulator of claim 1, wherein said upper electrode includes two of said first electrode portions, said second electrode portion being located between two of sad, first electrode portions and being spaced apart from each of said first electrode portions.

3. The optical modulator of claim 1, wherein the first length ranges from 100 μm to 300 μm.

4. The optical modulator of claim 1, wherein the second. length ranges from 50 μm to 150 μm.

5. The optical modulator of claim 1, wherein said light-emitting device is a semiconductor laser diode, and includes
a substrate, and
a first confinement layer, an active layer and a second confinement layer which are disposed on said substrate in such order, said first and second confinement layers having different conductivity types.

6. The optical modulator of claim 5, wherein said light-emitting device further includes a buffer layer interposed between said substrate and said first confinement layer.

7. The optical modulator of claim 5, wherein said light-emitting device further includes a waveguide unit that is disposed on said second confinement layer opposite to said active layer, said waveguide unit having a ridge waveguide extending in the X direction; and
wherein said at least one first electrode portion and said second electrode portion are separately disposed to cover an upper surface of said ridge waveguide.

8. The optical modulator of claim 7, wherein said waveguide unit includes
an etch stop layer disposed on said second confinement layer,
a capping layer disposed on said etch stop layer and having two first lateral portions and a first middle portion which is disposed between said first lateral portions and which is spaced apart from each of said first lateral portions, and
a contact layer having
a second middle portion disposed on said first middle portion such that said first and second middle portions together serve as said ridge waveguide, and
two second lateral portions disposed respectively on said first lateral portions so as to form two lateral waveguides at two opposite sides of said ridge waveguide,
said ridge waveguide defining two trenches respectively with said lateral waveguides so as to expose two portions of said etch stop layer.

9. The optical modulator of claim 8, wherein said light-emitting device further includes a passivation layer which includes two layer portions each extending to cover a respective one of said lateral waveguides and an inner surface of a respective one of said trenches.

10. The optical modulator of claim 9, wherein said upper electrode further includes
a first extending portion extending from said first electrode portion to cover said passivation layer, and
a second extending portion extending from said second electrode portion to cover said passivation layer.

11. The optical modulator of claim 8, wherein said light-emitting device further includes a grating structure that is interposed between said second confinement layer and said waveguide unit and that includes a plurality of grating strips, said grating strips extending in a Y direction transverse to the X direction, and being displaced from each other in the X direction, said grating strips in the direct-current modulated segment having a grating pitch ranging from 160 nm to 270 nm.

12. The optical modulator of claim 11, wherein said Grating structure further includes a first cladding layer and a second cladding layer which are configured to permit said grating strips to be disposed therebetween.

13. A method for manufacturing an optical modulator, comprising the steps of:
disposing a first confinement layer, an active layer and a second confinement layer on a substrate in such order, the first and second confinement layers having different conductivity types;
forming a waveguide unit on the second confinement layer, the waveguide unit including a ridge waveguide; and
forming an upper electrode on the ridge waveguide, the upper electrode including at least one first electrode portion for injecting a direct current and a second electrode segment for injecting an alternating current, the at least one first electrode portion and the second electrode portion being spaced apart from each other in an X direction, and having a first length and a second length in the X direction, respectively, the first length being greater than the second length.

14. The method of claim 13, wherein the first length ranges from 100 μm to 300 μm.

15. The method of claim 13, wherein the second length ranges from 50 μm to 150 μm.

16. The method of claim 13, further comprising, before forming the waveguide unit, disposing a grating structure on the second confinement layer.

17. The method of claim 13, further comprising a step of disposing a lower electrode on the substrate opposite to the first confinement layer.

18. The method. of claim 13, wherein the waveguide unit is formed by:
sequentially depositing an etch stop layer, a capping layer, and a contact layer on the second confinement layer; and
patterning the capping layer and the contact layer to form two trenches which expose two portions of the etch stop layer, such that the capping layer is formed into a first middle portion and two first lateral portions at two opposite sides of the first middle portion, and such that the contact layer is formed into a second middle portion and two second lateral portions, the second middle portion being disposed on the first middle portion to together serve as the ridge waveguide, the second lateral portions disposed respectively on the first lateral portions so as to form two lateral waveguides at two opposite sides of the ridge waveguide.

19. An optical modulator, comprising a light-emitting device and an upper electrode disposed on said light-emitting device,
said light-emitting device including
a substrate, and
a buffer layer, a first confinement layer, an active laver, a second confinement layer and a waveguide unit which are disposed on said substrate in such order,
said upper electrode including
at least one first electrode portion for injecting a direct current so as to form a direct-current modulated segment in said light-emitting device in a position beneath said at least one first electrode portion, and
a second electrode portion for injecting an alternating current so as to form an alternating-current modulated segment in said light-emitting device in a position beneath said second electrode portion, wherein said at least one first electrode portion and said second electrode portion are spaced apart from each other in an X direction, and have a first length and a second length in the X direction, respectively, the first length being greater than the second length.

20. The optical modulator of claim 19, wherein said first and second confinement layers have different conductivity types.
